(19) United States
(12) Patent Application Publication
(10) Pub. No.: US 2026/0287660 A1
(43) Pub. Date: Sep. 24, 2026

(54) METHOD OF INSPECTING SELF-DISCHARGE OF SECONDARY BATTERY

(71) Applicant: KABUSHIKI KAISHA TOYOTA JIDOSHOKKI, Kariya-shi, Aichi (JP)

(72) Inventor: Yuuhi SATO, Kariya-shi, Aichi (JP)

(73) Assignee: KABUSHIKI KAISHA TOYOTA JIDOSHOKKI, Kariya-shi, Aichi (JP)

(21) Appl. No.: 19/477,674

(22) PCT Filed: Mar. 27, 2024
(86) PCT No.: PCT/JP2024/012132

§ 371 Date: Oct. 22, 2025

(30) Foreign Application Priority Data
May 16, 2023 (JP) 2023-080705

(51) Int. Cl. G01R 31/3835

(52) U.S. Cl. CPC G01R 31/3835

(57) ABSTRACT

A method of inspecting self-discharge of a secondary battery including a plurality of secondary batteries connected in a battery module includes determining quality of each of the secondary batteries by allowing the secondary battery to self-discharge during a self-discharging period from a self-discharging start time to a self-discharging end time, calculating a voltage drop amount of each of the plurality of the secondary batteries during the self-discharging period based on a voltage at the self-discharging start time and a voltage at the self-discharging end time when the battery module is charged, and determining the quality of each of the plurality of the secondary batteries based on the voltage drop amount and a map in which a change in a SOC relative to a change in the voltage of the secondary battery when the secondary battery is allowed to self-discharge is associated with the voltage at the self-discharging start time.

### TECHNICAL FIELD

The present disclosure relates to a method of inspecting self-discharge of a secondary battery.

### BACKGROUND ART

A battery module includes a plurality of secondary batteries connected in series to each other. A manufacturing process of a secondary battery includes an inspecting process. The inspecting process includes a self-discharge inspection of the secondary battery. As disclosed in Patent Literature 1, the self-discharge inspection of the secondary battery is an inspection in which quality of the secondary battery is determined based on whether an amount of voltage drop of the secondary battery when each of the secondary batteries is allowed to self-discharge for a predetermined period is a threshold value or more.

### CITATION LIST

### Patent Literature

Patent Literature 1: Japanese Patent Application Publication No. 2012-221648

### SUMMARY OF INVENTION

### Technical Problem

In the self-discharge inspection of the secondary battery, after the battery module is set so that the battery module has a predetermined capacity, each of the secondary batteries is allowed to self-discharge. When the battery module is charged so as to reach the predetermined capacity, voltages of the secondary batteries may vary. Thus, even when the amount of voltage drop is the same among the secondary batteries, an amount of decrease in capacity of the secondary battery may not be the same among the secondary batteries. As a result, accuracy of the quality determination of the secondary battery may be decreased.

### Solution to Problem

A method of inspecting self-discharge of a secondary battery to solve the above-described problem is a method of inspecting self-discharge of a secondary battery including a plurality of secondary batteries connected in series in a battery module that includes determining quality of each of the secondary batteries by allowing the secondary battery to self-discharge during a self-discharging period from a self-discharging start time to a self-discharging end time, calculating a voltage drop amount of each of the plurality of the secondary batteries during the self-discharging period based on a voltage at the self-discharging start time and a voltage at the self-discharging end time of the secondary battery when the battery module is charged so that the battery module has a predetermined capacity, and determining the quality of each of the plurality of the secondary batteries based on the voltage drop amount and a map in which a change in a SOC relative to a change in the voltage of the secondary battery when the secondary battery is allowed to self-discharge is associated with the voltage at the self-discharging start time.

Even when the voltage at the self-discharging start time varies among the secondary batteries, the change in the SOC of each of the secondary batteries is obtained using the map in which the change in the SOC relative to the change in the voltage of the secondary battery when the secondary battery is allowed to self-discharge is associated with the voltage at the self-discharging start time. The quality of each of the secondary batteries is determined based on the map and the voltage drop amount, which may improve accuracy of the quality determination of the secondary battery.

In the above-described method of inspecting the self-discharge of the secondary battery, the determining of the quality of each of the plurality of the secondary batteries may include converting the voltage drop amount to a capacity decrease amount of the secondary battery based on the map and determining the quality of each of the plurality of the secondary batteries based on the capacity decrease amount.

In the above-described method of inspecting the self-discharge of the secondary battery, the determining of the quality of each of the plurality of the secondary batteries may include deriving an allowable voltage at the self-discharging end time based on the map and determining the quality of each of the plurality of the secondary batteries based on the voltage drop amount and the allowable voltage.

In the above-described method of inspecting the self-discharge of the secondary battery, the battery module may include a bipolar electrode having a positive electrode active material layer provided on one surface of a current collector and a negative electrode active material layer provided on the other surface of the current collector.

In the above-described method of inspecting the self-discharge of the secondary battery, each of the plurality of the secondary batteries may be allowed to self-discharge in a state where the SOC of the secondary battery is 10% or less.

In the above-described method of inspecting the self-discharge of the secondary battery, the secondary batteries each may include an olivine-type structure positive electrode active material.

### Advantageous Effects of Invention

According to the present invention, it is possible to improve accuracy of quality determination of a secondary battery.

### BRIEF DESCRIPTION OF DRAWINGS

FIG. 1 is a cross-sectional view of a battery module.

FIG. 2 is a circuit diagram illustrating the battery module and an inspecting device for a secondary battery.

FIG. 3 is a flowchart illustrating a method of inspecting self-discharge of the secondary battery.

FIG. 4 is a view showing a correlation between a voltage and a state of charge (SOC).

FIG. 5 is a flowchart illustrating a method of inspecting self-discharge of the secondary battery.

### DESCRIPTION OF EMBODIMENTS

### First Embodiment

The following will describe a first embodiment of a method of inspecting self-discharge of a secondary battery.

### Secondary Battery

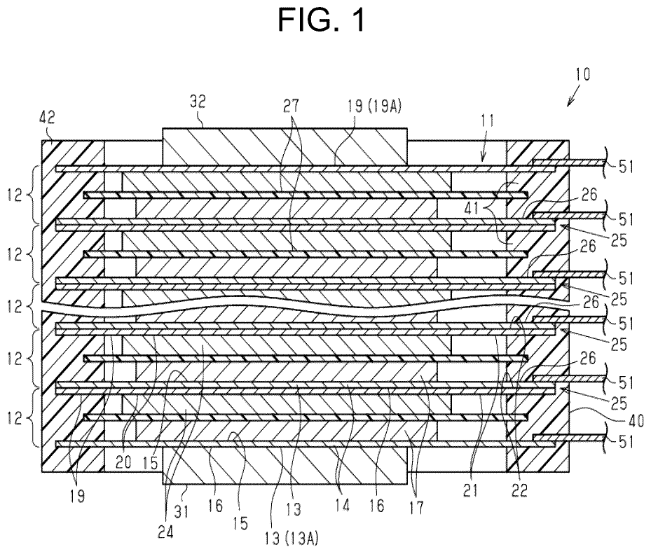

As illustrated in FIG. 1, a battery module 10 includes a stack 11. The stack 11 includes a plurality of secondary batteries 12 connected in series to each other. The plurality of the secondary batteries 12 are stacked. In the subsequent description, a direction in which the secondary batteries 12 are stacked is defined as a stacking direction.

Each of the secondary batteries 12 includes a positive electrode 13, a negative electrode 19, and a separator 27.

The positive electrode 13 includes a positive electrode current collector 14 and a positive electrode active material layer 17. The positive electrode current collector 14 is formed in a sheet shape. The positive electrode current collector 14 has a first surface 15 and a second surface 16. The first surface 15 and the second surface 16 are surfaces that are opposite from each other in a thickness direction of the positive electrode current collector 14.

The positive electrode active material layer 17 is provided on the first surface 15 of the positive electrode current collector 14. The positive electrode active material layer 17 contains a positive electrode active material that may absorb and desorb lithium ions as charge carriers. The positive electrode active material is, for example, a polyanion-based compound having an olivine-type structure, a lithium composite metal oxide having a layered rock-salt structure, and a metal oxide having a spinel structure. Examples of the olivine-type structure positive electrode active material include an olivine-type lithium iron phosphate (LiFePO4) and an olivine-type lithium manganese iron phosphate (LiMnFePO4). In the present embodiment, the positive electrode active material is an olivine-type lithium iron phosphate (LiFePO4).

The negative electrode 19 includes a negative electrode current collector 20 and a negative electrode active material layer 24. The negative electrode current collector 20 is formed in a sheet shape. The negative electrode current collector 20 includes a first surface 21 and a second surface 22. The first surface 21 and the second surface 22 are surfaces that are opposite from each other in a thickness direction of the negative electrode current collector 20.

The negative electrode active material layer 24 is provided on the first surface 21 of the negative electrode current collector 20. The negative electrode active material layer 24 contains a negative electrode active material that may absorb and desorb charge carriers such as lithium ions. Any simple substance, alloy, or compound that may absorb and desorb charge carriers such as lithium ions are usable as the negative electrode active material, and the negative electrode active material is not particularly limited. Examples of the negative electrode active material includes lithium, carbon, a metal compound, an element capable of being alloyed with lithium, a compound thereof, or the like. Examples of the carbon include natural graphite, artificial graphite, hard carbon (non-graphitizing carbon), and soft carbon (graphitizing carbon). Examples of the artificial carbon include highly oriented graphite, mesocarbon, and microbeads. Examples of the element capable of being alloyed with lithium include silicon (silicon) and tin. In this embodiment, the negative electrode active material is graphite.

The stack 11 includes bipolar electrodes 25. Each of the bipolar electrodes 25 includes a current collector 26, the positive electrode active material layer 17 provided on one surface of the current collector 26, the negative electrode active material layer 24 provided on the other surface of the current collector 26. The current collector 26 is formed by integrating the positive electrode current collector 14 and the negative electrode current collector 20 that are in contact with each other. For example, in each of the bipolar electrodes 25, the positive electrode current collector 14 and the negative electrode current collector 20 are joined to each other with the second surface 16 of the positive electrode current collector 14 and the second surface 22 of the negative electrode current collector 20 in contact with each other to form the current collector 26. Each of the bipolar electrodes 25 is formed by regarding the positive electrode current collector 14 and the negative electrode current collector 20 that are in contact with each other as the one current collector 26.

The positive electrode 13 that is provided at one end of the stack 11, of the positive electrodes 13, is defined as a positive terminal electrode 13A. The negative electrode 19 that is provided at the other end of the stack 11, of the negative electrodes 19, is defined as a negative terminal electrode 19A. The plurality of the bipolar electrodes 25 are interposed between the positive terminal electrode 13A and the negative terminal electrode 19A. The second surface 16 of the positive electrode current collector 14 in the positive terminal electrode 13A forms an outer surface of the stack 11. The second surface 22 of the negative electrode current collector 20 in the negative terminal electrode 19A forms an outer surface of the stack 11. The secondary battery 12 that is provided at the one end of the stack 11 includes the positive terminal electrode 13A and the negative electrode active material layer 24 in the bipolar electrode 25 adjacent to the positive terminal electrode 13A. The secondary battery 12 that is provided at the other end of the stack 11 includes the negative terminal electrode 19A and the positive electrode active material layer 17 in the bipolar electrode 25 adjacent to the negative terminal electrode 19A. The secondary batteries 12 that are provided between the secondary battery 12 at the one end of the stack 11 and the secondary battery 12 at the other end of the stack 11 each include the positive electrode active material layer 17 in one of the bipolar electrodes 25 and the negative electrode active material layer 24 in another bipolar electrode 25 adjacent to the one of the bipolar electrode 25.

The separator 27 is disposed between the positive electrode active material layer 17 and the negative electrode active material layer 24. The separator 27 keeps a distance between the positive electrode active material layer 17 and the negative electrode active material layer 24 to prevent a short circuit caused by contact of the positive electrode active material layer 17 with the negative electrode active material layer 24, while allowing charge carriers such as lithium ions to pass through the separator 27.

The battery module 10 includes a positive electrode conductive plate 31 and a negative electrode conductive plate 32. The positive electrode conductive plate 31 and the negative electrode conductive plate 32 are made of a metal material such as aluminum, copper, or stainless steel.

The positive electrode conductive plate 31 is electrically connected to the second surface 16 of the positive electrode current collector 14 in the positive terminal electrode 13A. The negative electrode conductive plate 32 is electrically connected to the second surface 22 of the negative electrode current collector 20 in the negative terminal electrode 19A. The battery module 10 is charged and discharged through terminals provided in the positive electrode conductive plate 31 and the negative electrode conductive plate 32.

The battery module 10 includes a sealing body 40. The sealing body 40 has a quadrilateral frame shape. The sealing body 40 includes first portions 41 and a second portion 42. The first portions 41 are located between the current collectors 26 arranged side by side, between the positive electrode current collector 14 in the positive terminal electrode 13A and the current collector 26 of the bipolar electrode 25 adjacent to the positive terminal electrode 13A, and between the negative electrode current collector 20 in the negative terminal electrode 19A and the current collector 26 of the bipolar electrode 25 adjacent to the negative terminal electrode 19A. The second portion 42 is located outside peripheral portions of the current collectors 26, the positive electrode current collector 14 in the positive terminal electrode 13A, and the negative electrode current collector 20 in the negative terminal electrode 19A. The sealing body 40 seals the stack 11.

The battery module 10 includes voltage detection lines 51. The voltage detection lines 51 are each formed in a long foil shape, for example. The voltage detection lines 51 are individually provided on the current collector 26 in each of the bipolar electrodes 25, the positive electrode current collector 14 in the positive terminal electrode 13A, and the negative electrode current collector 20 in the negative terminal electrode 19A. For example, the voltage detection lines 51 are individually joined to the current collector 26 in each of the bipolar electrodes 25, the positive electrode current collector 14 in the positive terminal electrode 13A, and the negative electrode current collector 20 in the negative terminal electrode 19A by ultrasonic welding. With this configuration, a voltage of one of the secondary batteries 12 is detectable using the two voltage detection lines 51 adjacent to each other in the stacking direction.

A part of each of the voltage detection lines 51 is covered with the sealing body 40. The voltage detection lines 51 extend toward an outside of the sealing body 40. A part of each of the voltage detection lines 51 is exposed to the outside of the sealing body 40. That is, the voltage detection lines 51 are drawn out to the outside of the sealing body 40 so that the voltages of the secondary batteries 12 are detectable using the voltage detection lines 51 outside the sealing body 40.

### Self-Discharge Inspection of Secondary Battery 12

A manufacturing process of the secondary battery 12 includes an inspecting process of the secondary battery 12. The inspecting process of the secondary battery 12 includes a self-discharge inspection of the secondary battery 12. The self-discharge inspection of the secondary battery 12 is performed to inspect, for example, a micro-short circuit in the secondary battery 12. The self-discharge inspection of the secondary battery 12 is performed using an inspecting device for the secondary battery 12.

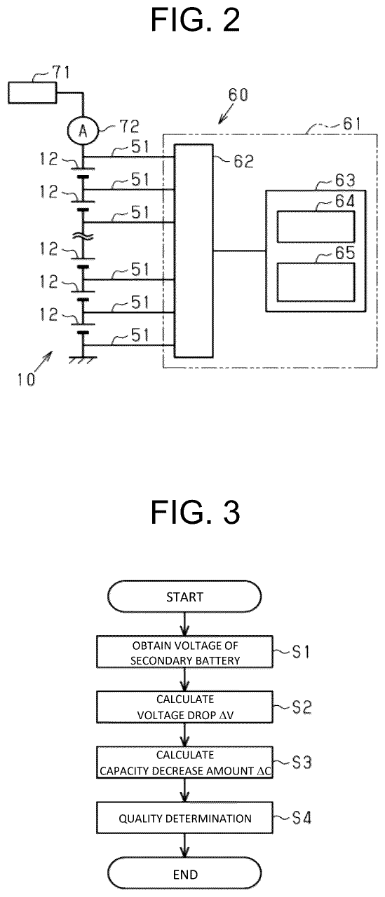

As illustrated in FIG. 2, the inspecting device 60 for the secondary battery 12 includes a self-discharge inspecting device 61. The self-discharge inspecting device 61 includes a voltage detection circuit 62. The voltage detection circuit 62 is, for example, an integrated circuit. The voltage detection circuit 62 has a plurality of ports to which the voltage detection lines 51 are connected. The voltage detection circuit 62 detects the voltages of the secondary batteries 12 based on an electric potential input from each of the voltage detection lines 51. The voltage of each of the secondary batteries 12 that is detected by the self-discharge inspection of the secondary battery 12 is an open circuit voltage (OCV).

The self-discharge inspecting device 61 includes a determining device 63. The determining device 63 is a device for checking whether a micro-short circuit occurs in the secondary battery 12 and determining quality of the secondary battery 12. The determining device 63 includes a processor 64 and a data storage memory 65. The processor 64 is, for example, a CPU (Central Processing Unit), a GPU (Graphics Processing Unit), or a DSP (Digital Signal Processor). The data storage unit 65 includes a RAM (Random Access Memory) and a Read Only Memory (ROM). The data storage unit 65 stores programs for performing the self-discharge inspection of the secondary battery 12. The data storage unit 65 stores program codes or commands configured to cause the processor 64 to execute processes. The data storage unit 65, that is, a computer readable medium includes any available medium that is accessible by a general purpose computer or a dedicated computer. The determining device 63 may include a hardware circuit such as ASIC (Application Specific Integrated Circuit) or an FPGA (Field Programmable Gate Array). The determining device 63, which is a processing circuit, may include one or more processors for operating in accordance with computer programs, one or more hardware circuits such as the ASIC or the FPGA, or a combination thereof.

The inspecting device 60 for the secondary battery 12 includes a charger 71 and a current sensor 72. The charger 71 applies a DC voltage to the battery module 10 to charge the battery module 10. The charger 71 includes, for example, a DC/DC converter that change an input voltage to an output voltage having a different voltage level. The current sensor 72 is connected in series to the battery module 10. The current sensor 72 detects a current flowing from the charger 71 to the battery module 10.

The charger 71 charges the battery module 10 so that the battery module 10 has a predetermined capacity. The predetermined capacity is set so that a SOC (State of Charge) of each of the plurality of the secondary batteries 12 in the battery module 10 is 10% or less, for example. The charger 71 charges the secondary batteries 12 while obtaining the SOC of each of the secondary batteries 12 by a current integration method. The charger 71 calculates an amount of change in a remaining capacity [Ah] of each of the secondary batteries 12 by obtaining a detection result of the current sensor 72. The charger 71 obtains the SOC of each of the secondary batteries 12 by dividing the amount of change in the remaining capacity of the secondary battery 12 by a full charge capacity [Ah] of the secondary battery 12.

The full charge capacity of each of the secondary batteries 12 used for the calculation of the SOC is a design standard value (ideal value). Actually, the full charge capacity of each of the secondary batteries 12 varies depending on a variation in a weight per area of at least one of the positive electrode active material layer 17 and the negative electrode active material layer 24 in the manufacturing process of the secondary battery 12. These variations in full charge capacity cause variations in SOC among the secondary batteries 12 at a time when the charging by the charger 71 has been completed.

### Method of Inspecting Self-Discharge of Secondary Battery 12

The method of inspecting the self-discharge of the secondary battery 12 is a method in which the quality of each of the secondary batteries 12 is determined based on a voltage drop amount ΔV1 of the secondary battery 12 when each of the plurality of the secondary batteries is allowed to self-discharge during a self-discharging period from a self-discharging start time to a self-discharging end time. The self-discharging start time is a point of time at which the secondary batteries 12 start to self-discharge. The self-discharging end time is a point of time when the self-discharging period has elapsed from the self-discharging start time. The self-discharging period is, for example, seven days. The self-discharging period may be changed as appropriate, for example, from four to ten days. When the secondary batteries 12 are allowed to self-discharge, an environmental temperature of the secondary batteries 12 is maintained at a constant temperature. The constant temperature is, for example, 25°. The constant temperature may be changed as appropriate, for example, within a range from 20° to 30°. For example, a temperature-controlled chamber is used in order to maintain the environmental temperature of the secondary batteries 12.

In the method of inspecting the self-discharge, for example, it is determined whether a micro-short circuit occurs in each of the secondary batteries 12. In a case where the micro-short circuit occurs, the voltage drop amount 66 V1 of the secondary battery 12 when the secondary battery 12 is allowed to self-discharge for the same period is larger than that in a case where no micro-short circuit occurs in the secondary battery 12. The method of inspecting the self-discharge of the secondary battery 12 is performed by the determining device 63. During the self-discharge inspection, each of the secondary batteries 12 is not connected to a load. That is, a decrease in the remaining capacity of each of the secondary batteries 12 during the self-discharge inspection is caused by the self-discharge.

As illustrated in FIG. 3, in Step S1, the determining device 63 obtains voltages of the plurality of the secondary batteries 12 in the battery module 10, which has been charged by the charger 71 so that the battery module 10 has the predetermined capacity, from the voltage detection circuit 62. The voltages of the secondary batteries 12 are obtained at the self-discharging start time and at the self-discharging end time. The voltages of the secondary batteries 12 at the self-discharging start time may vary because of the variations in full charge capacity. The voltages of the secondary batteries 12 at the self-discharging end time are lower than those at the self-discharging start time due to the self-discharge during the self-discharging period. In the self-discharge inspection, since the charging is performed so that the SOC of each of the secondary batteries 12 becomes 10% or less, each of the secondary batteries 12 is allowed to self-discharge in a state where the SOC of each of the secondary batteries 12 is 10% or less. The determining device 63 executes processes in Step S2 to Step S4 in each of the secondary batteries 12 from which the voltages have been obtained by the determining device 63. That is, the determining device 63 determines the quality of each of the plurality of the secondary batteries 12 in the battery module 10 formed by modularizing the secondary batteries 12.

In Step S2, the determining device 63 calculates the voltage drop amount ΔV1 of the secondary battery 12 during the self-discharging period. The voltage drop amount ΔV1 is a difference between the voltage of the secondary battery 12 at the self-discharging start time and the voltage of the secondary battery 12 at the self-discharging end time.

Next, in Step S3, the determining device 63 converts the voltage drop amount ΔV1 to a capacity decrease amount AC of the secondary battery 12 from the self-discharging start time until the self-discharging end time based on a map. In the map, a change in the SOC relative to a change in the voltage of the secondary battery 12 when the secondary battery 12 is allowed to self-discharge is associated with the voltage at the self-discharging start time.

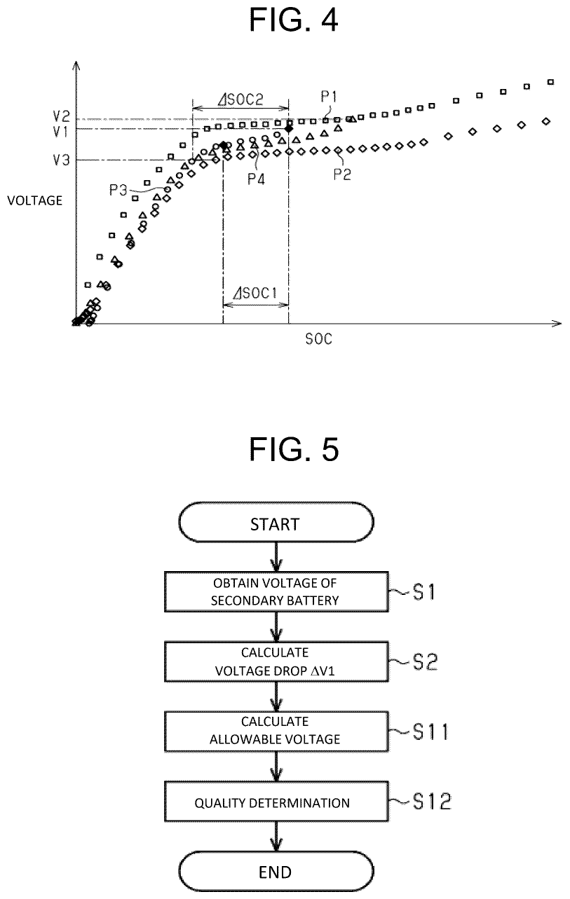

As shown in FIG. 4, there is a correlation between a voltage and a SOC in the secondary battery 12. This correlation is used to estimate the SOC of the secondary battery 12. In FIG. 4, points P1 marked with empty squares represent a correlation (charging curve) between a voltage and a SOC during a charging process. When the secondary battery 12 is charged, the SOC may be estimated using this correlation. Points P2 marked with empty diamonds represent a correlation (discharging curve) between a voltage and a SOC during a discharging process. When the secondary battery 12 is discharged, the SOC may be estimated using this correlation. Thus, even when the SOCs are the same, since hysteresis is observed between the voltage during the charging process and the voltage during the discharging process, there is an offset between the charging curve and the discharging curve.

The inventors have found that a correlation between a voltage and a SOC during a self-discharging process does not match any of the correlation between the voltage and the SOC during the charging process and the correlation between the voltage and the SOC during the discharging process. It is presumed that as the above-described hysteresis is larger, the offset between the correlation between the voltage and the SOC during the self-discharging process and the correlation between the voltage and the SOC during the charging process is increased, and the offset between the correlation between the voltage and the SOC during the self-discharging process and the correlation between the voltage and the SOC during the discharging process is increased.

Points P3 and P4 represent the change in the SOC relative to the change in the voltage of the secondary battery 12 when the secondary battery 12 is allowed to self-discharge. The voltage indicated by the points P3 and the voltage indicated by the points P4 are different from each other at the self-discharge start time. The points P3 marked with empty circles represent a correlation between a voltage and a SOC in the secondary battery 12 in a case where the voltage at the self-discharge start time is a first voltage V1. The points P4 marked with empty triangles represent a correlation between a voltage and a SOC in the secondary battery 12 in a case where the voltage at the self-discharge start time is a second voltage V2. Thus, the map associated the change in the SOC relative to the change in the voltage of the secondary battery 12 when the secondary battery 12 is allowed to self-discharge with the voltage at any self-discharging start time to define the correlation between the voltage of the secondary battery 12 and the SOC. As an example, FIG. 4 shows cases where the voltage at the self-discharging start time is the first voltage V1 or the second voltage V2; however, the map may include the voltages other than the first voltage V1 and the second voltage V2 as the voltage at the self-discharging start time. For example, the map preferably includes a plurality of voltages at the self-discharging start time in 0.01 [V] increments. For example, the map includes the voltage at the self-discharging start time within a range from 3.20 [V] to 3.25 [V].

The map is created in advance using the secondary battery 12 that is a good product having a full charge capacity of an ideal value and having no internal short circuit. More specifically, after the voltage of the secondary battery 12 having the full charge capacity of the ideal value is set to the first voltage V1, the secondary battery 12 is allowed to self-discharge and the change in the SOC of the secondary battery 12 relative to the change in the voltage of the secondary battery 12 is plotted. Then, the map is created by plotting the change in the SOC of the secondary battery 12 relative to the change in the voltage of the secondary battery 12 also in the voltages at the self-discharging start time other than the first voltage V1. This map is stored in a storage device such as the data storage unit 65 from which the map is readable by the determining device 63.

The determining device 63 converts the voltage drop amount ΔV1 to the capacity decrease amount ΔC of the secondary battery 12 based on the map. The determining device 63 selects the correlation corresponding to the voltage at the self-discharging start time of the secondary battery 12 to be a target for the quality determination, from the map. The determining device 63 selects the correlation corresponding to the voltage at the self-discharging start time, of the voltages at the self-discharging start time in the map, which is closest to the voltage at the self-discharging start time of the secondary battery 12 to be the target for the quality determination. For example, the determining device 63 selects the correlation represented by the points P3 when the voltage at the self-discharging start time obtained in Step S1 is closest to the first voltage V1, of the voltages at the self-discharging start time in the map. Then, the determining device 63 converts the voltage drop amount ΔV1 to a decrease amount ΔSOC1 of the SOC using the correlation corresponding to the voltage at the self-discharging start time of the secondary battery 12. Since the SOC is the remaining capacity of the secondary battery 12 expressed as a percentage, the decrease amount ΔSOC1 of the SOC is regarded as the capacity decrease amount ΔC. Thus, the capacity decrease amount AC may be the decrease amount ΔSOC1 of the SOC. The remaining capacity [Ah] of the secondary battery 12 is calculated from the SOC. Here, the ideal value may be used as the full charge capacity of the secondary battery 12. The capacity decrease amount ΔC may be an amount of decrease in the remaining capacity [Ah] of the secondary battery 12.

Next, in Step S4, the determining device 63 determines the quality of the secondary battery 12 based on the capacity decrease amount ΔC obtained in Step S3. The determining device 63 determines that the secondary battery 12 is a good product in a case where the capacity decrease amount ΔC is less than a reference value. The determining device 63 may determine that the secondary battery 12 is a defective product when the capacity decrease amount ΔC is equal to or greater than the reference value. In a case where the micro-short circuit occurs in the secondary battery 12, the capacity decrease amount ΔC when the secondary battery 12 is allowed to self-discharge for the same period is larger than that in a case where no micro-short circuit occurs. The capacity decrease amount ΔC when the micro-short circuit occurs in the secondary battery 12 is obtained in advance, and the reference value only needs to be determined based on this capacity decrease amount ΔC. When at least one of the plurality of the secondary batteries 12 in the battery module 10 is determined to be a defective product, the battery module 10 is disposed of.

### Operation of First Embodiment

In the self-discharge inspection of the secondary battery 12, after the battery module 10 is set so that the battery module 10 has the predetermined capacity, the secondary batteries 12 are allowed to self-discharge. The self-discharge inspection of the secondary battery 12 is an inspection in which the quality of each of the secondary batteries 12 is determined by allowing the secondary batteries 12 to self-discharge. Accordingly, in the self-discharge inspection of the secondary battery 12, the quality of the secondary battery 12 is preferably determined based on the amount [Ah] of decrease in the remaining capacity by the self-discharge. As described above, the full charge capacity of each of the secondary batteries 12 varies. For this reason, even when the amount of decrease in the remaining capacity by the self-discharge is the same among the secondary batteries 12, the voltage drop amount ΔV1 may not be the same value among the secondary batteries 12. As a result, when the quality of each of the secondary batteries 12 is determined based on the voltage drop amount ΔV1, accuracy of the quality determination of the secondary battery 12 may be decreased. In the first embodiment, the voltage drop amount ΔV1 is converted to the capacity decrease amount AC using the map. Then, the quality of each of the secondary batteries 12 is determined based on the capacity decrease amount ΔC.

### Advantageous Effects of First Embodiment

(1-1) Even when the voltage at the self-discharging start time varies among the secondary batteries 12, the change in the SOC of each of the secondary batteries 12 is obtained using the map. The quality of each of the secondary batteries 12 is determined based on the map and the voltage drop amount ΔV1, which may improve the accuracy of the quality determination. In the present embodiment, the determining device 63 converts the voltage drop amount ΔV1 to the capacity decrease amount ΔC based on the map. Then, the determining device 63 determines the quality of each of the secondary batteries 12 based on the capacity decrease amount ΔC. Since the quality of each of the secondary batteries 12 may be determined by the amount of decrease in the remaining capacity of the secondary battery 12 by the self-discharge, the accuracy of the quality determination may be improved.
(1-2) When each of the secondary batteries has the terminal used for the charging and the discharging, in the battery module formed by modularizing the secondary batteries, the remaining capacity of each of the secondary batteries is measured in advance, and each of the secondary batteries may be charged so that the secondary battery has a predetermined SOC. In this case, the voltage at the self-discharging start time is set to the same among the secondary batteries, so that the quality of each of the secondary batteries may be determined based on the voltage drop amount ΔV1.

In contrast, the battery module 10 having the bipolar electrodes 25 is formed by modularizing the plurality of the secondary batteries 12 connected to each other inside the sealing body 40. In the secondary batteries 12 each having the bipolar electrode 25, the terminal that is exposed to the outside the sealing body 40 is not provided on each of the secondary batteries 12. This makes it hard to individually charge the secondary batteries 12. In the secondary batteries 12 each having the bipolar electrode 25, all the modularized secondary batteries 12 are charged by the same charging current. As a result, the SOCs of the plurality of the secondary batteries 12 are not set to be the same, so that the quality of each of the secondary batteries 12 is hardly determined based on the voltage drop amount ΔV1.

The method of inspecting the self-discharge of the secondary battery 12 in the first embodiment may determine the quality of each of the secondary batteries 12 with high accuracy even when the SOC varies among the plurality of the secondary batteries 12. Thus, even in the secondary batteries 12 each having the bipolar electrode 25, the quality of each of the secondary batteries 12 may be determined with high accuracy.
(1-3) In the method of inspecting the self-discharge of the battery module 10, the secondary batteries 12 are allowed to self-discharge in the state where the SOC of each of the secondary batteries 12 is 10% or less. Each of the secondary batteries 12 formed by combining the positive electrode containing an iron-containing olivine such as an olivine-type lithium iron phosphate or an olivine-type lithium manganese iron phosphate with the negative electrode has a plateau region. In the plateau region, since the change in the OCV relative to the change in the SOC is substantially constant, in a case where each of the secondary batteries 12 is allowed to self-discharge in the plateau region, the voltage drop amount ΔV1 becomes small, and this makes it hard to determine the quality of the secondary battery 12. When each of the secondary batteries 12 self-discharges in a non-plateau region such as a region in which the SOC is 15% or less, preferably 12% or less, further preferably 10% or less, or more further preferably 9% or less, the voltage drop amount ΔV1 relative to the change in the SOC is increased, which may calculate the capacity decrease amount ΔC more accurately.
(1-4) The secondary batteries 12 each include the olivine-type structure positive electrode active material. In each of the secondary batteries 12, the hysteresis is observed in the voltage during the charging process and the voltage in the discharging process. Although the degree of the hysteresis varies depending on materials, the hysteresis is large in a lithium ion secondary battery, in particular, in a lithium ion secondary battery including the olivine-type structure positive electrode active material. The self-discharge inspection is performed on such secondary batteries 12 using the map, which may improve the accuracy of the quality determination.

### Second Embodiment

The following will describe a second embodiment of the method of inspecting self-discharge of the secondary battery. In the second embodiment, the process executed by the determining device is different from that in the first embodiment.

As illustrated in FIG. 5, the determining device 63 executes a process in Step S11 instead of Step S3 in the first embodiment. In Step S11, the determining device 63 derives an allowable voltage at the self-discharging end time based on the map. For example, an allowable decrease amount ΔSOC2 of the SOC during the self-discharging period is determined in advance. The decrease amount ΔSOC2 of the SOC only needs to be set to a value smaller than an amount of decrease in the SOC obtained in advance when a micro-short circuit occurs in the secondary battery 12. The determining device 63 selects the correlation corresponding to the voltage at the self-discharging start time of the secondary battery 12 to be a target for the quality determination. As an example, the following will describe a case where the correlation represented by the points P3 is selected.

As shown in FIG. 4, the determining device 63 subtracts the allowable decrease amount ΔSOC2 of the SOC during the self-discharging period from the SOC corresponding to the voltage at the self-discharging start time of the secondary battery 12 and derives a voltage V3 corresponding to the SOC obtained by the subtraction from the correlation. This voltage V3 is an allowable voltage at the self-discharging end time of the secondary battery 12.

In Step S12, the determining device 63 determines the quality of the secondary battery 12 based on the voltage drop amount ΔV1 and the allowable voltage V3. When a value obtained by subtracting the voltage drop amount ΔV1 from the voltage at the self-discharging start time, that is, the voltage at the self-discharging end time is the allowable voltage V3 or greater, the determining device 63 determines that the secondary battery 12 is a good product. When the voltage at the self-discharging end time is less than the allowable voltage V3, the determining device 63 determines that the secondary battery 12 is a defective product.

### Advantageous Effects of Second Embodiment

(2-1) The determining device 63 may derive the allowable voltage V3 at the self-discharging end time based on the map. Then, the determining device 63 may determine the quality of the secondary battery 12 based on this voltage V3. This may improve the accuracy of the quality determination.

### MODIFIED EXAMPLE

Each of the embodiments may be modified as follows. The present embodiments and the following modified examples may be combined with each other as long as they do not technically contradict each other.

In each of the embodiments, the secondary battery 12 may include an electrode in which active material layers of the same polarity are provided on opposite sides of the current collector. In this case, each of the plurality of the secondary batteries 12 has a terminal used for the charging and the discharging.

In each of the embodiments, the quality of the secondary battery 12 may be determined by a person.

In the first embodiment, the determining device 63 may determine that the secondary battery 12 is a good product when the capacity decrease amount AC is within a predetermined range from a reference value. The determining device 63 may determine that the secondary battery 12 is a defective product when the capacity decrease amount ΔC is outside the predetermined range from the reference value. The reference value is, for example, a median of the capacity decrease amounts ΔC of the plurality of the secondary batteries 12 in the battery module 10. The predetermined range is, for example, set to a value corresponding to a range from 2σ to 4σ, wherein o represents a standard deviation.

In the second embodiment, Step S11 may be performed between Step S1 and Step S2. Moreover, Step S11 and Step S2 may be performed at the same time.

### REFERENCE SIGNS LIST

10 battery module
12 secondary battery
17 positive electrode active material layer
24 negative electrode active material layer
25 bipolar electrode
26 current collector

1. A method of inspecting self-discharge of a secondary battery including a plurality of secondary batteries connected in series in a battery module, the method comprising:
determining quality of each of the secondary batteries by allowing the secondary battery to self-discharge during a self-discharging period from a self-discharging start time to a self-discharging end time;
calculating a voltage drop amount of each of the plurality of the secondary batteries during the self-discharging period based on a voltage at the self-discharging start time and a voltage at the self-discharging end time of the secondary battery when the battery module is charged so that the battery module has a predetermined capacity; and
determining the quality of each of the plurality of the secondary batteries based on the voltage drop amount and a map in which a change in a SOC relative to a change in the voltage of the secondary battery when the secondary battery is allowed to self-discharge is associated with the voltage at the self-discharging start time.

2. The method of inspecting the self-discharge of the secondary battery according to claim 1, wherein
the determining of the quality of each of the plurality of the secondary batteries includes:
converting the voltage drop amount to a capacity decrease amount of the secondary battery based on the map; and
determining the quality of each of the plurality of the secondary batteries based on the capacity decrease amount.

3. The method of inspecting the self-discharge of the secondary battery according to claim 1, wherein
the determining of the quality of each of the plurality of the secondary batteries includes:
deriving an allowable voltage at the self-discharging end time based on the map; and
determining the quality of each of the plurality of the secondary batteries based on the voltage drop amount and the allowable voltage.

4. The method of inspecting the self-discharge of the secondary battery according to claim 1, wherein
the battery module includes a bipolar electrode having a positive electrode active material layer provided on one surface of a current collector and a negative electrode active material layer provided on the other surface of the current collector.

5. The method of inspecting the self-discharge of the secondary battery according to claim 1, wherein
each of the plurality of the secondary batteries is allowed to self-discharge in a state where the SOC of the secondary battery is 10% or less.

6. The method of inspecting the self-discharge of the secondary battery according to claim 1, wherein
the secondary batteries each include an olivine-type structure positive electrode active material.
